(19) United States
(12) Patent Application Publication
(10) Pub. No.: US 2012/0043527 A1
(43) Pub. Date: Feb. 23, 2012

(54) LIGHT EMITTING DEVICE

(75) Inventors: Liang Ding, Singapore (SG); Mingbin Yu, Singapore (SG); Guo Qiang Patrick Lo, Singapore (SG)

(73) Assignee: AGENCY FOR SCIENCE, TECHNOLOGY AND RESEARCH

(21) Appl. No.: 12/859,587

(22) Filed: Aug. 19, 2010

(51) Int. Cl. H01L 33/06; H01L 21/04

(52) U.S. Cl. 257/28; 438/22; 257/E33.01; 257/E33.069; 257/E21.04; 977/761

(57) ABSTRACT

According to embodiments of the present invention, a light emitting device is provided. The light emitting device includes: an active region comprising at least one p-i-n junction, the at least one p-i-n junction comprising a p-doped region, an intrinsic region and an n-doped region; a first contact; and a second contact, wherein the active region is disposed between the first contact and the second contact; and wherein a voltage applied to the first contact and the second contact produces a current configured to flow between the first contact and the second contact in a direction substantially parallel to a surface of the intrinsic region of the active region configured to emit a light. According to embodiments of the present invention, the intrinsic region includes a multiple quantum well (MQW) such that a current injected flows laterally in a direction substantially parallel to the surface of the wells of the MQW.

### TECHNICAL FIELD

Various embodiments relate to a light emitting device and a method of forming the light emitting device.

### BACKGROUND

Since the successful demonstration of low-loss waveguides, high-speed optical modulators and photo-detectors, among other devices, with complementary metal-oxide-semiconductor (CMOS) processes, silicon (Si)-based light sources have been considered a challenging step to achieve in silicon photonics technology.

There has been intensive study and research for the purpose of realization of Si-based light emitting diodes (LEDs) since the first discovery of strong photoluminescence (PL) from porous silicon.

Low dimensional silicon structures have, conventionally, been the preferred platform to produce Si-based light sources. A lot of efforts based on various techniques have been made to synthesize low dimensional silicon, such as silicon nanowires, silicon superlattice structures and silicon nanocrystals (nc-Si).

However, it is not practical to use porous silicon to make reliable electrical and optical light sources because porous silicon is not compatible with the CMOS process and porous silicon is also sensitive to the surrounding atmosphere.

As for devices employing silicon nanocrystals embedded in dielectrics, one of the disadvantages is the difficulty in controlling the nanocrystal size. In addition, the low current injection efficiency of the device is also an issue due to the reason that the majority of the active region comprises dielectric material.

Research has also been focused on silicon superlattice structures, such as ultra-thin silicon/silicon dioxide (Si/SiO₂) multilayer structure or multiple quantum well (MQW) structure, prepared by the chemical plasma deposition (CVD) process, which is compatible with CMOS technology.

However, devices employing Si/SiO₂ multiple quantum well (MQW) are conventionally based on the vertical-current-injection mechanism. Such vertical-current-injection structures employing vertical-current-injection have a polycrystalline silicon (poly-Si) or a metal electrode on top of the active materials, resulting in significant reduction in the output light intensity.

Furthermore, for vertical-current-injection structures, the voltage is applied across a couple of layers of highly insulating dielectric films, leading to very low current injection efficiency and a high turn-on voltage.

A further disadvantage of conventional structures employing vertical-current-injection is the large difference in the carrier densities in the individual quantum well layers. In a conventional quantum well LED or a laser device, electrons and holes are injected into the MQW in a direction vertical to the surface of the wells. The mobility of electrons is much higher than holes due to the smaller effective mass of electrons, and electrons move faster than holes when a bias is applied. Thus, the electron and hole densities are higher in quantum wells near the p-electrode than in those near the n-electrode under a forward bias. Accordingly, in a conventional vertical MQW light emitting device, the number of quantum wells cannot be increased arbitrarily, due to the large difference in the carrier intensities in individual quantum wells. This prevents a conventional vertical-current-injection MQW light source from achieving a high gain of power.

### SUMMARY

According to an embodiment, a light emitting device is provided. The light emitting device may include: an active region comprising at least one p-i-n junction, the at least one p-i-n junction comprising a p-doped region, an intrinsic region and an n-doped region; a first contact; and a second contact, wherein the active region is disposed between the first contact and the second contact; and wherein a voltage applied to the first contact and the second contact produces a current configured to flow between the first contact and the second contact in a direction substantially parallel to a surface of the intrinsic region of the active region configured to emit a light.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a perspective view of a light emitting device, according to one embodiment.

FIG. 1B shows an expanded sectional view of a multiple quantum well of the light emitting device of the embodiment of FIG. 1A.

FIG. 2A shows a perspective view of a light emitting device, according to one embodiment.

FIG. 2B shows an expanded sectional view of a multiple quantum well of the light emitting device of the embodiment of FIG. 2A.

FIG. 2C shows a top view of the light emitting device of the embodiment of FIG. 2A.

FIG. 2D shows a sectional view of the active region of the light emitting device taken along the line A-A′ of FIG. 2C.

FIG. 2E is a TEM image showing a sectional view of the active region of the light emitting device taken at the square B of FIG. 2C.

FIG. 2F is a TEM image showing an expanded sectional view of the multiple quantum well of FIG. 2E.

FIG. 3 shows a flow chart illustrating a method of forming a light emitting device, according to various embodiments.

FIGS. 4A to 4D show cross-sectional views of a fabrication process to manufacture a light emitting device, according to various embodiments.

FIG. 5 shows a plot of Raman data for a number of nanocrystalline Si/SiO₂ multilayer samples according to various embodiments.

FIGS. 6A and 6B show a side view and a top view, respectively, of a light emitting device, according to one embodiment.

FIG. 7A shows photographs of electroluminescence patterns under reverse bias for the light emitting device fabricated according to the embodiment of FIG. 2A.

FIG. 7B shows a photograph of electroluminescence patterns under reverse bias for the light emitting device fabricated according to the embodiment of FIG. 1A.

FIG. 8 shows a plot of electroluminescence spectra under different reverse bias voltages for the light emitting device fabricated according to the embodiment of FIG. 2A.

FIG. 9 shows a plot of I-V characteristics and integrated EL intensity for the light emitting device fabricated according to the embodiment of FIG. 2A.

FIG. 10 shows a plot of electroluminescence spectra for the lateral-current-injection and vertical-current-injection light emitting devices, according to various embodiments.

FIG. 11 shows a plot of electroluminescence spectra for samples of the light emitting device fabricated and annealed at different temperatures, in accordance with the embodiment of FIG. 2A.

FIG. 12 shows a plot of electroluminescence spectra for samples of the light emitting device fabricated with different interdigitated finger spacings, in accordance with the embodiment of FIG. 2A.

FIG. 13 shows a plot of electroluminescence spectra for samples of the light emitting device fabricated with different nanocrystalline silicon layer thicknesses, in accordance with the embodiment of FIG. 2A.

FIG. 14 shows a schematic side view of a structure with a light emitting device with Fabry-Perot (F-P) cavity, according to one embodiment.

FIG. 15 shows a schematic side view of a waveguided light source, according to one embodiment.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Various embodiments provide a light emitting device that may employ a lateral-current-injection mechanism, without or with reduced at least some of the associated disadvantages of conventional devices.

Various embodiments may provide a light emitting device having a lateral-current-injection structure such that a current or charge carriers may be injected laterally into the structure to flow in a direction substantially parallel to or along the conducting layers (or along the surface of the wells) of the multiple quantum well structures, in contrast to current being injected in a direction vertical to the surface of the wells for conventional vertical-current-injection structures. Accordingly, the various embodiments may advantageously eliminate the problem of difference in the carrier densities in different individual quantum well layers, thereby achieving a relatively higher gain in power.

By providing a lateral-current-injection structure, various embodiments may provide increased light extraction efficiency and current injection efficiency.

In the context of various embodiments, the term “light emitting device” may mean a device that may generate and emit light. The light emitting device may include an active region. The term “active region” may mean a region where charge carriers are injected into in order to generate the emitted light.

In various embodiments, the active region may include an intrinsic region. The intrinsic region may include a multiple quantum well structure.

A quantum well, as understood in the art, is a potential well that confines particles to two dimensions such that the particles occupy a planar region, which would otherwise be free to move in three dimensions. A quantum well may be formed, for example by sandwiching a first material (or a layer of the first material) with a second material (or layers of the second materials) having a wider energy bandgap. Accordingly, the term “multiple quantum well” may mean a plurality of such quantum wells, having a multilayer configuration of alternating layers of differing first and second materials.

In various embodiments, the multiple quantum well structure may include alternating layers of conducting layers and non-conducting layers. The term “conducting layers” may mean layers in which charge carriers or current may flow while the term “non-conducting layers” may mean layers in which no charge carriers or current may flow. Accordingly, carriers injected into the active region may be confined to flow in the conducting layers of the multiple quantum well structure.

In various embodiments, the active region may include at least one p-i-n junction. The p-i-n junction, as generally known in the art of semiconductor, may include a p-doped region, an intrinsic region and an n-doped region. The term “p-doped” may mean a host material (generally a semiconductor) that is doped with dopant atoms that may accept weakly-bound outer electrons from the host material, thereby creating vacancies left behind by the electrons, known as holes. This results in an electrically conductive p-type semiconductor with an excess number of mobile holes (positively charged carriers). Such dopants are also generally referred to as acceptors. Accordingly, the term “p-doped region” may mean a region of p-type semiconductor with an excess of mobile holes.

The term “intrinsic” may mean undoped, such that the term “intrinsic region” may mean a region of undoped semiconductor or host material, without the presence of any significant dopant elements or atoms. Therefore, the properties of the intrinsic semiconductor may determine the number of charge carriers in the semiconductor. As generally understood, the number of electrons and the number of holes in intrinsic semiconductors may be equal.

The term “n-doped” may mean a host material (generally a semiconductor) that is doped with dopant atoms that may provide extra conduction electrons to the host material, thereby resulting in an electrically conductive n-type semiconductor with an excess number of mobile electrons (negatively charged carriers). Such dopants are also generally referred to as donors. Accordingly, the term “n-doped region” may mean a region of n-type semiconductor with an excess number of mobile electrons.

In various embodiments, the host material may be silicon, which is a Group IV element. In various embodiments, the host material may be polycrystalline silicon. The p-doped region may be implanted with Group III dopants or elements, for example boron (B), to form a p-type semiconductor region. The n-doped region may be implanted with Group V dopants or elements, for example phosphorus (P), to form an n-type semiconductor region.

In further embodiments, the p-doped region may be doped with a relatively high amount of acceptor dopants to form a p⁺-type semiconductor region. In further embodiments, the n-doped region may be doped with a relatively high amount of donor dopants to form an n⁺-type semiconductor region. The term “p⁺-type semiconductor” may mean a semiconductor in which the excess mobile hole concentration is very large. The term “n⁺-type semiconductor” may mean a semiconductor in which the excess mobile electron concentration is very large.

In various embodiments, the intrinsic region may include a multiple quantum well structure. The multiple quantum well structure may include alternating layers of conducting layers and non-conducting layers.

In various embodiments, the active region may include a plurality of p-i-n junctions, each p-i-n junction including a p-doped region, an intrinsic region and an n-doped region. In further embodiments, adjacent p-i-n junctions of the plurality of p-i-n junctions may be configured back-to-back to form a p-i-n-i-p structure or an n-i-p-i-n structure.

In various embodiments, the conducting layers of the multiple quantum wells of the intrinsic regions of the plurality of p-i-n junctions may be in electrical communication with each other. In various embodiments, the intrinsic regions of the plurality of p-i-n junctions may be arranged in an interdigitated structure.

In the context of various embodiments, the term “contact” may mean a contact region where electrical signals, for example a voltage or a current, may be provided. In various embodiments, the contact may be provided in electrical communication with the active region. In various embodiments, two contacts may be provided, in which the active region may be disposed in between the two contacts. Each of the contacts may be a doped contact, such as a p-doped contact or an n-doped contact.

The term “p-doped contact” may mean a contact including a p-type semiconductor with an excess number of mobile holes. The term “n-doped contact” may mean a contact including an n-type semiconductor with an excess number of mobile electrons.

The active region may be disposed in between the contacts such that the interface between the intrinsic region and the p-region and the interface between the intrinsic region and the n-region are substantially perpendicular to the interfaces between the active region and the contacts. In further embodiments, the interface between the intrinsic region and the p-region and the interface between the intrinsic region and the n-region may be provided at an angle to the interfaces between the active region and the contacts.

In alternate embodiments, more than two contacts may be provided.

In various embodiments, the active region may be disposed in between a first contact and a second contact, for example a p-doped contact and an n-doped contact. The active region may include at least one p-i-n junction such that the interface between the intrinsic region and the p-doped region and the interface between the intrinsic region and the n-doped region are substantially perpendicular to the interface between the active region and the p-doped contact and the interface between the active region and the n-doped contact.

In the context of various embodiments, the term “lateral-current-injection” may mean that a voltage that is applied to the first contact and the second contact may cause a current to be injected into the active region through a side of the active region, corresponding to the interface between the first contact and the active region. Subsequently, the current may exit from a second side of the active region, the second side being opposite to the side of the active region from which the current is injected. This second side of the active region may correspond to the interface between the second contact and the active region.

In various embodiments, the current or charge carriers injected into the active region may flow between the first contact and the second contact, for example from the first contact, along or in a direction substantially parallel to the conducting layers of the multiple quantum well structures, to the second contact. The direction of the flow of the current or charge carriers may be substantially parallel to the surface of the intrinsic region of the active region configured to emit light. The surface may be the top surface of the intrinsic region. Accordingly, various embodiments provide a lateral-current-injection structure where a voltage or a bias may be fully applied across the active region and in particular, across the conducting layers of the multiple quantum well structures within the active region.

In further embodiments, the current or charge carriers injected into the active region may flow between the first contact and the second contact, for example from the first contact, along or in a direction substantially parallel to the conducting layers of the multiple quantum well structures, to the second contact. The direction of the flow of the current or charge carriers may be substantially parallel to the interface of the intrinsic region with the p-doped region and the interface of the intrinsic region with the n-doped region. Accordingly, various embodiments provide a lateral-current-injection structure where a voltage or a bias may be fully applied across the active region and in particular, across the conducting layers of the multiple quantum well structures within the active region.

In the context of various embodiments, the term “Bragg reflector” may mean a structure including multiple layers of alternating materials that may result in periodic variation in the effective refractive index of the Bragg reflector. This may be achieved by providing alternating layers of varying refractive index or by varying other characteristics of the alternating layers, for example the thickness of the layers, to modify the effective refractive index. The structure of the Bragg reflector may result in a partial reflection, at each interface or boundary between the layers, of an optical wave incident on the Bragg reflector.

Various embodiments provide a silicon-based light emitting device. Various embodiments may provide an efficient low-voltage lateral-current-injection CMOS-compatible light emitting device based on silicon/silicon dioxide (Si/SiO₂) multiple quantum well (MQW) structure. MQW structures are provided as they offer relatively more active volume than, for example, a single layer of silicon.

The MQW may include alternating layers (or films) of a conducting layer, for example nanocrystalline silicon (nc-Si), and a non-conducting layer, for example silicon dioxide (SiO₂). Each layer of the conducting layers, eg. nc-Si layers, may be an ultra thin layer. In one embodiment, the MQW may include ten periods of alternating ultra thin nc-Si layers and SiO₂ layers. In further embodiments, the MQW may include five periods of alternating ultra thin nc-Si layers and SiO₂ layers or eight periods of alternating ultra thin nc-Si layers and SiO₂ layers. In various embodiments, the nc-Si layers may have a thickness ranging from about 1.5 nm to about 15 nm, e.g. a thickness ranging from about 2 nm to about 10 nm, and the SiO₂ layers may have a thickness ranging from about 1 nm to 10 nm, e.g. a thickness ranging from about 1 nm to about 5 nm or about 3 nm to about 5 nm. In various embodiments, the SiO₂ layers may have a thickness of about 1 nm, about 3 nm or about 5 nm. However, it should be appreciated that there is no limitation on the thickness of the SiO₂ layers. In various embodiments, the nc-Si layers may have a thickness of about 2 nm, about 3 nm, about 5 nm, about 7 nm or about 10 nm.

Various embodiments may provide a light emitting device exhibiting relatively strong electroluminescence (EL) in the wavelengths ranging from about 450 nm to about 850 nm when the device is reverse-biased at a voltage range of about 6 V to about 18 V and at a current range of about 1 mA to about 100 mA. In further embodiments, the light emitting device may exhibit relatively strong electroluminescence (EL) in the wavelengths ranging from about 450 nm to about 550 nm, about 450 nm to about 750 nm or about 550 nm to about 750 nm. In further embodiments, the light emitting device may be reverse-biased at a voltage of about 6 V, about 9 V, about 12 V, about 15 V or about 18 V. In further embodiments, the light emitting device may be reverse-biased at a current of about 1 mA, about 5 mA, about 10 mA, about 20 mA, about 50 mA or about 100 mA. Various embodiments may provide a light emitting device that exhibits a linear relationship between the EL intensity and the reverse current.

Various embodiments may provide a lateral-current-injection structure for the light emitting device, where a voltage or a bias may be fully applied across the conducting layers (e.g. the ultra thin nc-Si layers) of the Si/SiO₂ multiple quantum well structures, thereby reducing the working voltage of the light emitting device and increasing the light extraction efficiency and the current injection efficiency. In contrast, for a light emitting device employing a vertical-current-injection structure with Si/SiO₂ multiple quantum well structures, the voltage is applied across dielectrics. Accordingly, the external quantum efficiency of the light emitting device of various embodiments may be approximately 20 times higher than that of the conventional vertical-current-injection light emitting devices. The light emission of the light emitting devices of various embodiments may originate from the impact ionization due to the hot carriers generated in the ultra-thin nc-Si layers when the device is reverse-biased.

Various embodiments may provide a light emitting device which advantageously do not require top electrodes on the device or electrodes over the active region. Accordingly, various embodiments may provide enhanced light emission. Further, various embodiments may provide a versatile technology platform, where light-extraction and monochromaticity enhancement structures or techniques may be integrated with the light emitting device. Such structures or techniques may be applied onto the light emission window of the light emitting device.

In addition, as a result of the absence of electrodes over the active region, various embodiments may provide an electrically-pumped waveguided light source in the field of silicon photonics.

Various embodiments may further provide narrow line emission and large area surface emission.

Further, various embodiments may provide a monolithically integrated light source with a low turn-on voltage that may be compatible with CMOS circuits.

In various embodiments, a method of forming a light emitting device is provided. The method may include providing an active region comprising at least one p-i-n junction, the at least one p-i-n junction comprising a p-doped region, an intrinsic region and an n-doped region; providing a first contact; and providing a second contact, wherein the active region is disposed between the first contact and the second contact; and wherein a voltage applied to the first contact and the second contact produces a current configured to flow between the first contact and the second contact in a direction substantially parallel to a surface of the intrinsic region of the active region configured to emit a light.

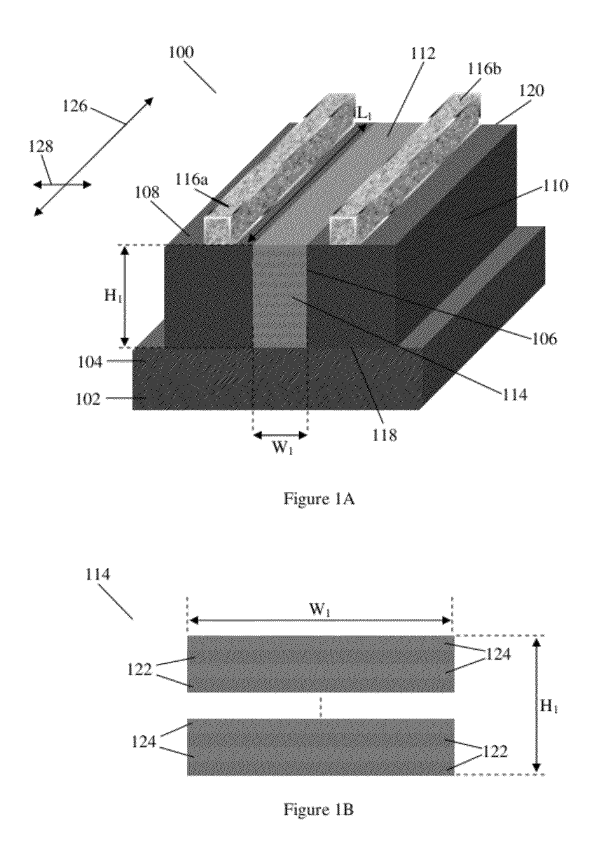

FIG. 1 shows a perspective view of a light emitting device 100 provided on a substrate 102 and an intermediate dielectric layer 104, in accordance with various embodiments. The substrate 102 may be silicon. The dielectric layer 104 may be a layer of silicon dioxide (SiO₂).

In various embodiments, the light emitting device 100 may include an active region 106 disposed between or sandwiched by a p-doped contact 108 and an n-doped contact 110. The active region 106 may include an intrinsic region. The intrinsic region may include a multiple quantum well (MQW) 114. The active region 106 may have the dimensions of length L₁, width W₁ and height H₁, as shown in FIG. 1A, such that the active region 106 may have a volume defined by L₁×W₁×H₁. The active region 106 includes a light emission window, as defined by the surface 112 having the area L₁×W₁, where light generated by the light emitting device 100 may be emitted. The length L₁ may be about 1 mm, the width W₁ may be about 1 μm and the height H₁ may be in the range of about 50 nm to about 130 nm, depending on the number of layers in the multiple quantum well 114. In various embodiments, the length L₁ may be about 0.3 mm, about 0.5 mm, about 0.8 mm, about 1.5 mm or about 2 mm, the width W₁ may be about 0.5 μm, about 2 μm or about 3 μm and the height H₁ may be about 50 nm, about 60 nm, about 80 nm, about 100 nm or about 130 nm. However, it should be appreciated that L₁, W₁ and H₁ may have any dimensions.

The active region 106 may include the multiple quantum well (MQW) 114. The multiple quantum well 114 may include alternating layers of conducting layers 122 and non-conducting layers 124, as shown in FIG. 1B. The conducting layers 122 may be ultra thin layers. The MQW 114 may be provided throughout the entire length L₁ of the active region 106, extending from the surface 118 to the surface 120. In various embodiments, the conducting layers 122 may be nanocrystalline silicon (nc-Si) layers while the non-conducting layers 124 may be silicon dioxide (SiO₂) layers. In further embodiments, the conducting layers 122 may be layers of silicon rich oxide, silicon rich nitride, germanium or nanolayers of Groups III-V elements. In further embodiments, the non-conducting layers 124 may be dielectric layers or films, for example layers of silicon nitride (Si₃N₄) or hafnium oxide (HfO₂). In various embodiments, the number of the conducting layers 122 and the number of the non-conducting layers 124 may be ten each, thereby providing ten periods. In further embodiments, the number of the conducting layers 122 and the number of the non-conducting layers 124 may be five each (five periods), eight each (eight periods)or twelve each (twelve periods). However, it should be appreciated that the multiple quantum well 114 may have any number of the conducting layers 122 and the non-conducting layers 124.

In various embodiments, each of the p-doped contact 108 and the n-doped contact 110 may include polycrystalline silicon (poly-Si). The p-doped contact 108 may be implanted with Group III dopants or elements to form a p-type semiconductor. In various embodiments, the p-doped contact 108 may be implanted with the dopant boron (B) to form a p-type semiconductor. The n-doped contact 110 may be implanted with Group V dopants or elements to form an n-type semiconductor. In various embodiments, the n-doped contact 110 may be implanted with the dopant phosphorus (P) to form an n-type semiconductor. In further embodiments, the p-doped contact 108 may be doped with a relatively high amount of dopants to form a p⁺-type semiconductor. In further embodiments, the n-doped contact 110 may be doped with a relatively high amount of dopants to form an n⁺-type semiconductor.

The light emitting device 100 may further include an electrode 116a in contact with the p-doped contact 108 and an electrode 116b in contact with the n-doped contact 110. Accordingly, the electrodes 116a and 116b are in electrical communication with the p-doped contact 108 and the n-doped contact 110, respectively. In various embodiments, the electrodes 116a and 116b may be metal electrodes. In a preferred embodiment, the electrodes 116a and 116b may be made of aluminium.

In various embodiments, the active region 106, the p-doped contact 108 and the n-doped contact 110 and the electrodes 116a and 116b may be configured to extend in a direction substantially parallel to the longitudinal axis, as represented by the arrow 126, of the light emitting device 100.

In various embodiments, when a voltage is applied between the electrodes 116a and 116b, a current may flow from the p-doped contact 108, through the conducting layers 122 of the multiple quantum well 114 to the n-doped contact 110 in a substantially lateral direction, as represented by the arrow 128, or a current may flow in the opposite direction from the n-doped contact 110 through the conducting layers 122 of the multiple quantum well 114 to the p-doped contact 108, depending on whether the light emitting device 100 is forward biased or reverse biased. In various embodiments, the direction of the current flow between the p-doped contact 108 and the n-doped contact 110, for example flowing from the p-doped contact 108, may be along or in a direction substantially parallel to the surface 112 of the intrinsic region of the active region 106 where light generated by the light emitting device 100 may be emitted, to the n-doped contact 110.

The embodiment of FIG. 1A may provide line emission of the generated light.

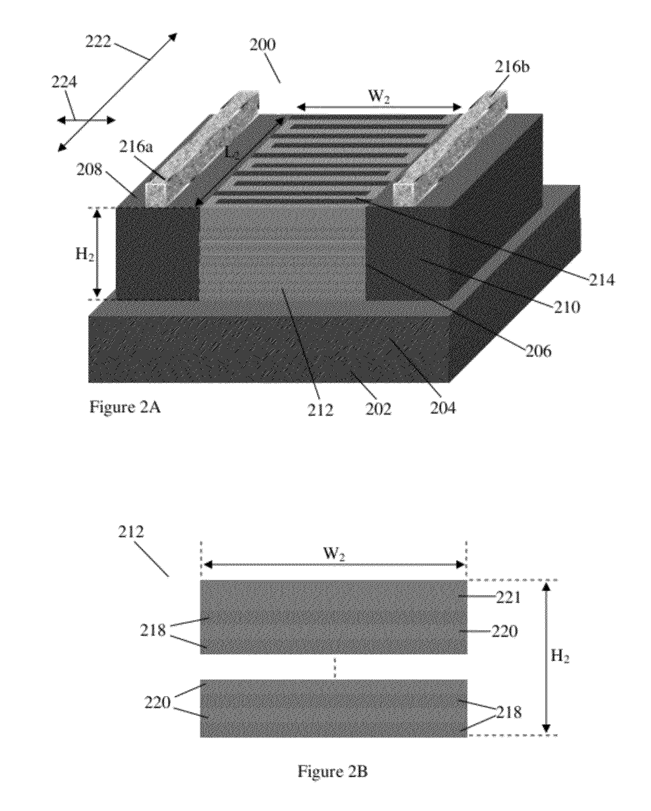

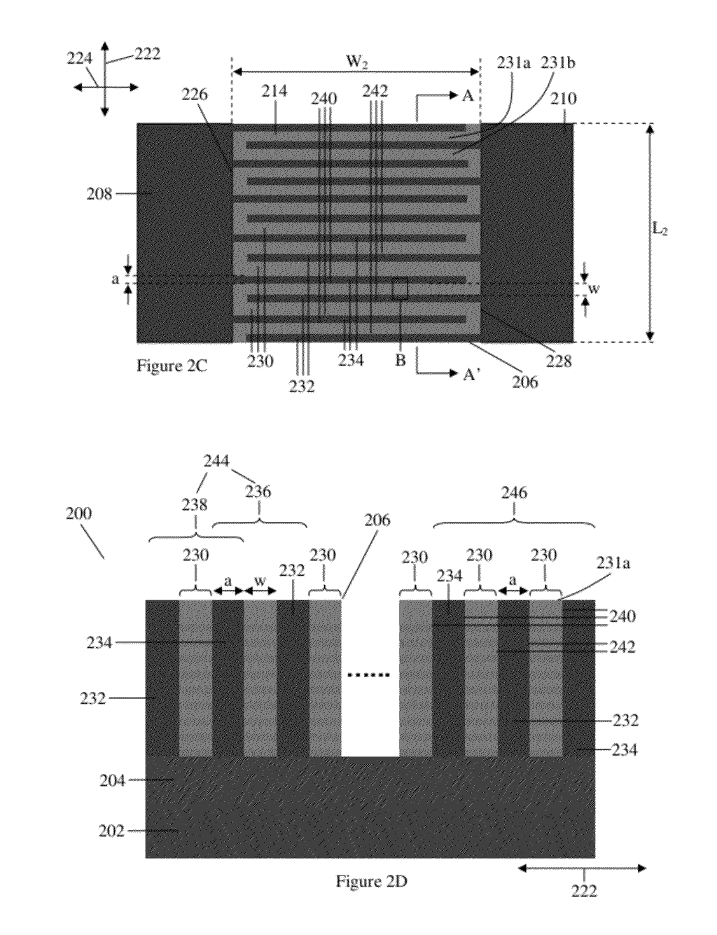

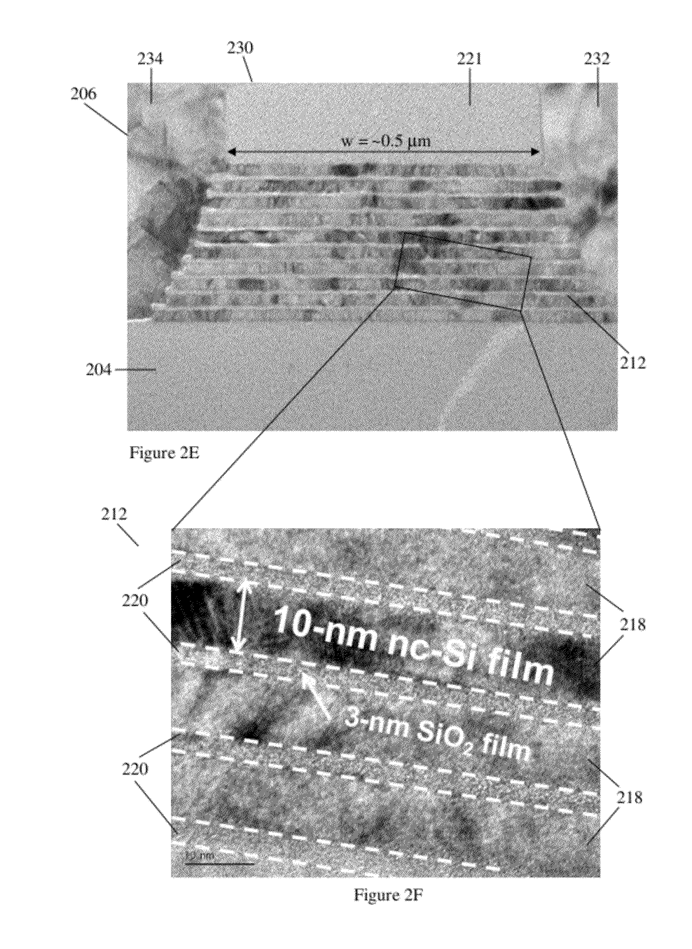

FIG. 2A shows a perspective view of a light emitting device 200 provided on a substrate 202 and an intermediate dielectric layer 204, in accordance with various embodiments. The substrate 202 may be silicon. The dielectric layer 204 may be a layer of silicon dioxide (SiO₂).

In various embodiments, the light emitting device 200 may include an active region 206 disposed between or sandwiched by a p-doped contact 208 and an n-doped contact 210. The active region 206 may have the dimensions of length L₂, width W₂ and height H₂, as shown in FIG. 2A, such that the active region 206 may have a volume defined by L₂×W₂×H₂. The active region 206 includes a light emission window, as defined by the area L₂×W₂, where light generated by the light emitting device 200 may be emitted. The length L₂ may be about 1 mm while the width W₂ may be about 1 mm, such that the light emission window area size may be approximately about 1 mm². The height H₂ may be in the range of about 50 nm to about 500 nm. In various embodiments, the length L₂ may be about 0.3 mm, about 0.5 mm, about 0.8 mm, about 1.5 mm or about 2 mm, the width W₂ may be about 0.3 mm, about 0.5 mm, about 0.8 mm, about 1.5 mm or about 2 mm and the height H₂ may be about 50 nm, about 60 nm, about 80 nm, about 100 nm, about 150 nm, about 200 nm, about 300 nm, about 400 nm or about 500 nm. However, it should be appreciated that L₂, W₂ and H₂ may have any dimensions.

The active region 206 may include a multiple quantum well (MQW) structure 212. The MQW 212 may include alternating layers of conducting layers 218 and non-conducting layers 220, as shown in FIG. 2B. The conducting layers 218 may be ultra thin layers. The MQW 212 may also include a passivation layer 221. In various embodiments, the number of the conducting layers 218 and the number of the non-conducting layers 220 may be ten each, thereby providing ten periods. In further embodiments, the number of the conducting layers 218 and the number of the non-conducting layers 220 may be five each (five periods), eight each (eight periods)or twelve each (twelve periods). However, it should be appreciated that the MQW 212 may have any number of the conducting layers 218 and the non-conducting layers 220. The number of the conducting layers 218 and the number of the non-conducting layers 220 may determine the dimension of H₂.

The thickness of the conducting layers 218 may be in the range of about 1.5 nm to about 15 nm while the thickness of the non-conducting layers 220 may be about 1 nm to about 10 nm. In various embodiments, the thickness of the conducting layers 218 may be in the range from about 2 nm to about 10 nm, e.g. in the range from about 2 nm to about 5 nm, e.g. about 2 nm, about 3 nm, about 5 nm, about 7 nm and about 10 nm. In various embodiments, the thickness of the non-conducting layers 220 may be in the range from about 1 nm to about 5 nm or about 3 nm to about 5 nm, e.g. about 1 nm, about 3 nm or about 5 nm. However, it should be appreciated that there is no limitation on the thickness of the non-conducting layers 220.

In various embodiments, the conducting layers 218 may be nanocrystalline silicon (nc-Si) layers, the non-conducting layers 220 may be silicon dioxide (SiO₂) layers and the passivation layer 221 may be a layer of silicon dioxide (SiO₂). In further embodiments, the conducting layers 218 may be layers of silicon rich oxide, silicon rich nitride, germanium or nanolayers of Groups III-V elements. In further embodiments, the non-conducting layers 220 may be dielectric layers or films, for example layers of silicon nitride (Si₃N₄) or hafnium oxide (HfO₂).

In various embodiments, the MQW 212 may be arranged in an interdigitated structure 214 in the active region 206, as shown in FIG. 2A.

In various embodiments, each of the p-doped contact 208 and the n-doped contact 210 may include polycrystalline silicon (poly-Si). The p-doped contact 208 may be implanted with Group III dopants or elements to form a p-type semiconductor. In various embodiments, the p-doped contact 208 may be implanted with the dopant boron (B) to form a p-type semiconductor. The n-doped contact 210 may be implanted with Group V dopants or elements to form an n-type semiconductor. In various embodiments, the n-doped contact 210 may be implanted with the dopant phosphorus (P) to form an n-type semiconductor. In further embodiments, the p-doped contact 208 may be doped with a relatively high amount of dopants to form a p⁺-type semiconductor. In further embodiments, the n-doped contact 210 may be doped with a relatively high amount of dopants to form an n⁺-type semiconductor.

The light emitting device 200 may further include an electrode 216a in contact with the p-doped contact 208 and an electrode 216b in contact with the n-doped contact 210. Accordingly, the electrodes 216a and 216b are in electrical communication with the p-doped contact 208 and the n-doped contact 210, respectively. In various embodiments, the electrodes 216a and 216b may be metal electrodes. In a preferred embodiment, the electrodes 216a and 216b may be made of aluminium.

In various embodiments, the active region 206, the p-doped contact 208 and the n-doped contact 210 and the electrodes 216a and 216b may be configured to extend in a direction substantially parallel to the longitudinal axis, as represented by the arrow 222, of the light emitting device 200.

In various embodiments, when a voltage is applied between the electrodes 216a and 216b of the light emitting device 200, a current may flow from the p-doped contact 208, through the conducting layers 218 of the MQW 212 to the n-doped contact 210 in a substantially lateral direction, as represented by the arrow 224, or a current may flow in the opposite direction from the n-doped contact 210 through the conducting layers 218 of the multiple quantum wells 212 to the p-doped contact 208, depending on whether the light emitting device 200 is forward biased or reverse biased. The lateral direction, as represented by the arrow 224, is substantially perpendicular to the longitudinal axis, as represented by the arrow 222, of the light emitting device 200.

In various embodiments, the direction of the current flow between the p-doped contact 208 and the n-doped contact 210, for example flowing from the p-doped contact 208, may be along or in a direction substantially parallel to the surface of the intrinsic region of the active region 206 where light generated by the light emitting device 200 may be emitted, to the n-doped contact 210. The surface of the intrinsic region of the active region 206 where light generated by the light emitting device 200 may be emitted may be the top surface of the intrinsic region. Accordingly, various embodiments provide lateral-current-injection of charge carriers into the active region 206.

In various embodiments, a forward biasing voltage in the range of about 0 V to about 15 V may be applied to the light emitting device 200. In various embodiments, in order to induce light emission from the light emitting device 200, a reverse biasing voltage in the range of about 0 V to about 20 V, or in other words, a biasing voltage of about 0 V to about −20 V, may be applied to the light emitting device 200. In various embodiments, the applied biasing voltage may be −18 V, −15 V, −12 V, −10 V, −8 V, −6 V, 0 V, 4 V, 8 V or 10 V.

FIG. 2C shows a top view of the light emitting device 200 of the embodiment of FIG. 2A. For illustration purposes, electrodes are not shown in FIG. 2C. The active region 206 is disposed between the p-doped contact 208 and the n-doped contact 210 such that the interface 226 between the active region 206 and the p-doped contact 208 and the interface 228 between the active region 206 and the n-doped contact 210 are substantially parallel to the longitudinal axis 222.

In various embodiments, the active region 206 may include an interdigitated structure 214. The interdigitated structure 214 includes fingers representing the n-doped regions 232 or the p-doped regions 234, with the intrinsic regions 230 disposed in between the fingers. Accordingly, the interdigitated structure 214 may include alternating regions of doped regions, such as the n-doped regions 232 or the p-doped regions 234, and intrinsic regions 230. With this arrangement, a plurality of p-i-n junctions are provided in the active region 206, with each p-i-n junction including a p-doped region 234, an intrinsic region 230 and an n-doped region 232.

In various embodiments, the interfaces 240 between the p-doped regions 234 and the intrinsic regions 230 and the interfaces 242 between the n-doped regions 232 and the intrinsic regions 230 may be substantially perpendicular to the interface 226 between the active region 206 and the p-doped contact 208 and the interface 228 between the active region 206 and the n-doped contact 210.

In various embodiments, the interfaces 240 between the p-doped regions 234 and the intrinsic regions 230 and the interfaces 242 between the n-doped regions 232 and the intrinsic regions 230 may be substantially perpendicular to the longitudinal axis 222.

Accordingly, various embodiments provide a light emitting device 200 including a p-doped contact 208, an n-doped contact 210 and an active region 206 disposed between the p-doped contact 208 and n-doped contact 210, the active region 206 including at least one p-i-n junction, the at least one p-i-n junction comprising a p-doped region 234, an intrinsic region 230 and an n-doped region 232, wherein a voltage applied to the p-doped contact 208 and the n-doped contact 210 produces a current configured to flow in a direction substantially parallel to the interface 240 of the intrinsic region 230 with the p-doped region 234 and the interface 242 of the intrinsic region 230 with the n-doped region 232. In various embodiments, a voltage applied to the p-doped contact 208 and the n-doped contact 210 produces a current configured to flow between the p-doped contact 208 and the n-doped contact 210 in a direction substantially parallel to the surface, for example 231a, 231b of the intrinsic region 230 of the active region 206, where light may be emitted.

In further embodiments, the plurality of p-i-n junctions may be arranged such that the interfaces 240 between the intrinsic regions 230 and the p-doped regions 234 and the interfaces 242 between the intrinsic regions 230 and the n-doped regions 232 are provided at an angle to the interface 226 between the active region 206 and the p-doped contact 208 and the interface 228 between the active region 206 and the n-doped contact 210.

In various embodiments, the intrinsic regions 230 may include multiple quantum well 212, as shown in FIG. 2B. The interdigitated structure 214 may have about 2 to about 5 periods, about 2 to about 8 periods, about 2 to about 12 periods or about 2 to about 20 periods of the intrinsic regions 230. In various embodiments, the interdigitated structure 214 may have about 2, about 3, about 5, about 8, about 10, about 12, about 15 or about 20 periods of the intrinsic regions 230.

Each intrinsic region 230 may have the width w, representing the finger spacing, and each of the n-doped regions 232 or the p-doped regions 234 may have the finger width a. The finger spacing w may be in the range of about 0.5 μm to about 3 μm. In various embodiments, the finger spacing w may be about 0.5 μm, about 1 μm, about 1.5 μm, about 2 μm, about 2.5 μm or about 3 μm. The finger width a may be about 5 μm or about 10 μm.

In various embodiments, each of the p-doped region 234 and the n-doped region 232 may include polycrystalline silicon (poly-Si). The p-doped region 234 may be implanted with the dopant boron (B) to form a p-type semiconductor. The n-doped region 232 may be implanted with the dopant phosphorus (P) to form an n-type semiconductor. In further embodiments, the p-doped region 234 may be doped with a relatively high amount of dopants to form a p⁺-type semiconductor. In further embodiments, the n-doped region 232 may be doped with a relatively high amount of dopants to form an n⁺-type semiconductor.

FIG. 2D shows a sectional view of the active region 206 of the light emitting device 200 taken along the line A-A′ of FIG. 2C. The active region 206 may be configured such that an intrinsic region 230 is provided in between a p-doped region 234 and an n-doped region 232 to form a p-i-n junction 236 or a n-i-p junction 238.

As a p-i-n junction 236 and an n-i-p junction 238 only differ in configuration and not their operations, p-i-n junctions 236 and n-i-p junctions 238 will be collectively known as p-i-n junctions from hereon.

In various embodiments, as a result of the interdigitated structure 214, the active region 206 may include a plurality of p-i-n junctions 236, 238. Further, the active region 206 may be provided such that adjacent p-i-n junctions, for example 236, 238 are configured back-to-back and share either a common p-doped region or a common n-doped region to form either an n-i-p-i-n structure 244 or a p-i-n-i-p structure 246, respectively.

In various embodiments, the plurality of p-i-n junctions, for example 236, 238, may be configured substantially parallel to each other.

In various embodiments, the intrinsic regions 230 of the plurality of p-i-n junctions, for example 236, 238, may be in electrical communication with each other. Accordingly, the conducting layers 218 of the MQW 212 of the intrinsic regions 230 of the plurality of p-i-n junctions, for example 236, 238, may be in electrical communication with each other.

In alternate embodiments, only a single p-i-n junction may be provided in the active region 206.

FIG. 2E shows a transmission electron microscopy (TEM) image illustrating a sectional view of the active region 206 of the light emitting device 200 taken at the square B of FIG. 2C. FIG. 2E shows part of an active region 206 on a dielectric layer 204 of silicon dioxide (SiO₂). The active region 206 includes the p-doped region 234 of p⁺-type semiconductor polycrystalline silicon, the intrinsic region 230 and the n-doped region 232 of n⁺-type semiconductor polycrystalline silicon. The intrinsic region 230 includes the multiple quantum well (MQW) structure 212, including the passivation layer 221 of silicon dioxide (SiO₂). The finger spacing w is estimated to be about 0.5 μm.

FIG. 2F shows a TEM image illustrating an expanded sectional view of the multiple quantum wells 212 of FIG. 2E. The multiple quantum wells 212 include alternating layers of conducting layers 218 of nanocrystalline layers (nc-Si) and non-conducting layers 220 of silicon dioxide (SiO₂). The thickness of the conducting layers 218 is estimated to be about 10 nm. The thickness of the non-conducting layers 220 is estimated to be about 3 nm.

The embodiments of FIGS. 2A to 2F advantageously provide enhanced carrier injection and enhanced surface emission of the generated light.

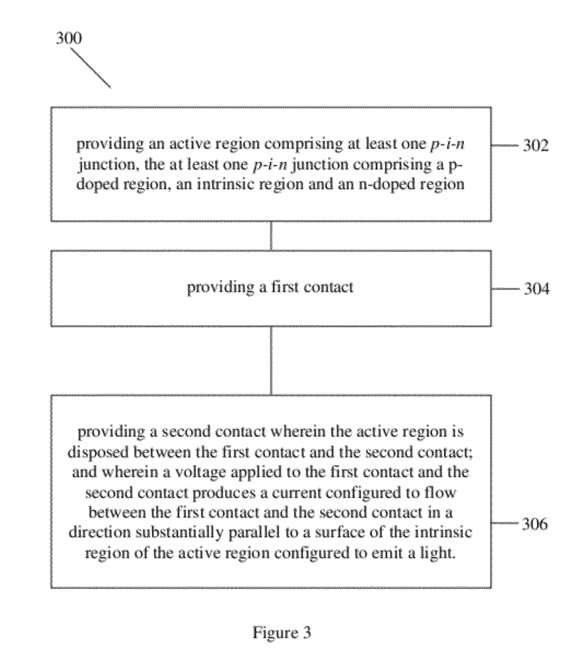

FIG. 3 shows a flow chart 300 illustrating a method of forming a light emitting device, according to various embodiments.

At 302, an active region comprising at least one p-i-n junction, the at least one p-i-n junction comprising a p-doped region, an intrinsic region and an n-doped region is provided.

At 304, a first contact is provided.

At 306, a second contact is provided, wherein the active region is disposed between the first contact and the second contact; and wherein a voltage applied to the first contact and the second contact produces a current configured to flow between the first contact and the second contact in a direction substantially parallel to a surface of the intrinsic region of the active region configured to emit a light.

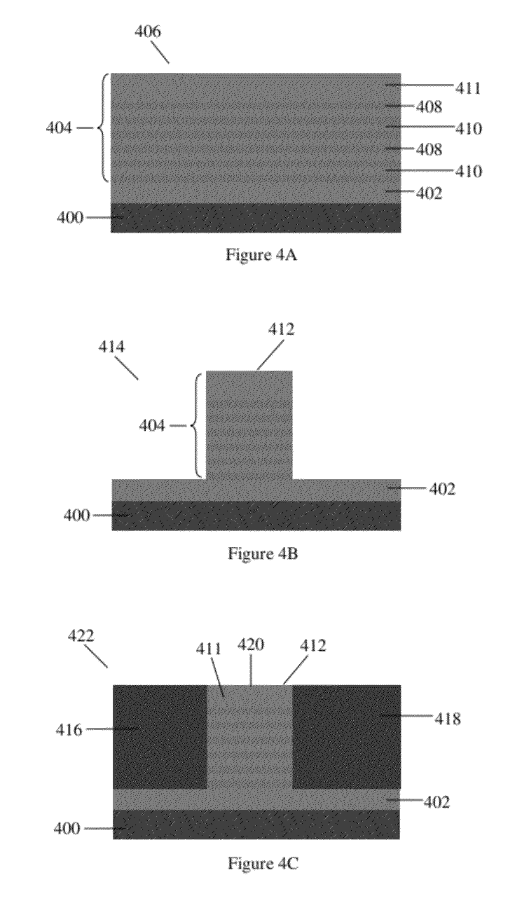

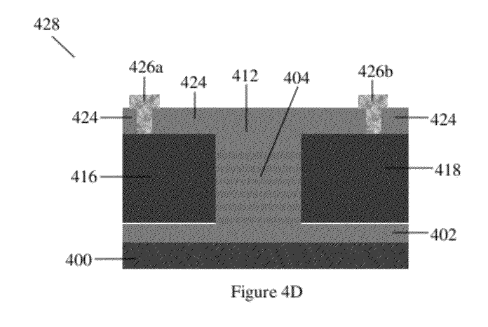

FIGS. 4A to 4D show cross-sectional views of a fabrication process to manufacture a light emitting device, according to various embodiments.

In FIG. 4A, a substrate 400 may be provided. The substrate 400 may be silicon. A dielectric oxide layer 402 may be grown on the substrate 400 via a thermal oxide growth process. The dielectric oxide layer 402 may be a layer of silicon dioxide (SiO₂).

A multiple quantum well (MQW) structure 404 is then formed via deposition using the plasma-enhanced chemical vapor deposition (PECVD) process on the dielectric oxide layer 402 to form the structure 406. The MQW 404 includes alternating layers of conducting layers 408 and non-conducting layers 410. The MQW 404 also includes a passivation layer 411 on the top. The use of the PECVD process offers control in the deposition of the conducting layers 408 and the non-conducting layers 410 of the MQW 404.

During the PECVD process, the alternating layers of conducting layers 408 and non-conducting layers 410 for the MQW structure 404 are deposited layer by layer, one layer at a time. A layer of amorphous silicon is grown, followed by a layer of silicon dioxide (SiO₂). The deposition process is repeated until an MQW 404 with the required number of layers is formed, followed by deposition of the passivation layer 411 of silicon dioxide (SiO₂). The structure 406 is then annealed to convert the layers of amorphous silicon to nanocrystalline silicon (nc-Si) to form the conducting layers 408. The annealing temperatures may be in the range of about 700° C. to about 1200° C. In various embodiments, the annealing temperatures may be 700° C., 900° C., 1000° C., 1100° C. or 1150° C. In various embodiments, the annealing process may be performed for a duration of about 0.5 hour, 1 hour, 1.5 hour or 2 hours.

Selective patterning may then be carried out to define an active region on the structure 406, followed by etching until the dielectric oxide layer 402 to form the active region 412, as shown in FIG. 4B. The active region 412 includes the MQW structure 404.

A layer of amorphous silicon is then grown on the structure 414 of FIG. 4B using the low pressure chemical vapor deposition (LPCVD) process, followed by an annealing process to convert the amorphous silicon to polycrystalline silicon. Implantation of dopants are then carried out to form a p-doped contact and an n-doped contact, followed by a rapid thermal annealing process to activate the dopants. Selective patterning and etching may then be carried out to define a light emission window by etching through the layer of polycrystalline silicon to expose the silicon dioxide (SiO₂) passivation layer 411 on the active region 412. FIG. 4C shows the structure 422 that may be formed.

The structure 422 includes the p-doped contact 416 and the n-doped contact 418. As a result of the patterning and etching process, a light emission window 420 may be provided.

In various embodiments, the dopant implantation process is carried out such that the p-doped contact 416 may be implanted with the dopant boron (B) to form a p-type semiconductor. The n-doped contact 418 may be implanted with the dopant phosphorus (P) to form an n-type semiconductor. In further embodiments, the p-doped contact 416 may be doped with a relatively high amount of dopants to form a p⁺-type semiconductor. In further embodiments, the n-doped contact 418 may be doped with a relatively high amount of dopants to form an n⁺-type semiconductor.

A cladding oxide layer may then be deposited on the structure 422 of FIG. 4C. Openings are created through the cladding layer until the p-doped contact 416 and the n-doped contact 418, followed by the formation of electrodes, through the openings.

FIG. 4D shows the final structure 428 that may be formed. The structure 428 includes the cladding oxide layer 424. The structure 428 further includes the electrodes 426a and 426b formed through the openings through the cladding oxide layer 424 to contact the p-doped contact 416 and the n-doped contact 418, respectively. Accordingly, the electrodes 426a and 426b are in electrical communication with the p-doped contact 416 and the n-doped contact 418, respectively.

In various embodiments, the cladding oxide layer 424 may be a layer of silicon dioxide (SiO₂). The electrodes 426a and 426b may be metal electrodes. In a preferred embodiment, the electrodes 426a and 426b may be made of aluminium (Al).

### Fabrication

### Deposition of Nanocrystalline Si/SiO₂ Multilayers for the Multiple Quantum Well Structure.

The fabrication of the light emitting device of various embodiments will now be described as follows, by way of examples and not limitations.

A light emitting device was fabricated with an active region with ten periods of alternating ultra-thin nanocrystalline silicon (nc-Si) layers and silicon dioxide (SiO₂) layers. The alternating ultra-thin nc-Si layers and SiO₂ layers were deposited by plasma enhanced chemical vapor deposition (PECVD). The thickness of the nc-Si layers that were deposited ranged from about 2 nm to about 10 nm for different samples, while the thickness of the SiO₂ layers that were deposited was about 3 nm.

Amorphous silicon (a-Si) was used as the starting material for the formation of the nc-Si layers. Ten periods of alternating a-Si and SiO₂ layers were deposited on top of a layer of about 500 nm thick thermal SiO₂ on an 8-inch silicon wafer to form the multiple quantum well structures of the light emitting device of various embodiments.

The ultra-thin a-Si layers were deposited under a radio frequency (RF) power of about 100 W at a chamber pressure of about 4 Torr, using silane (SiH₄) as the source gas, diluted by helium (He). The flow rates of SiH₄ and He were about 25 sccm and about 2000 sccm, respectively.

The SiO₂ layers were deposited under a radio frequency (RF) power of about 250 W at a chamber pressure of about 3 Torr, using silane (SiH₄) and nitrous oxide (N₂O) as the source gases. The flow rates of SiH₄ and N₂O were about 40 sccm and about 2000 sccm, respectively.

During the deposition of the a-Si and SiO₂ layers, the temperature of the silicon wafer was maintained at about 400° C.

Subsequently, high temperature annealing was carried out in a nitrogen (N₂) environment to induce nanocrystallization of the a-Si layers, leading to the formation of the nc-Si layers. The annealing process was carried out for a duration of 1 hour at various temperatures ranging from about 600° C. to about 1150° C. at a step interval of about 50° C.

Micro-Raman measurements were performed at a wavelength of about 325 nm on a number of nanocrystalline Si/SiO₂ multilayer or MQW samples to evaluate the effects of the annealing process on the nanocrystallization of the a-Si layers. For the purpose of micro-Raman measurements, a layer of SiO₂ with a thickness of about 2 μm was deposited on the silicon substrate prior to the deposition of the multilayers by PECVD in order to isolate the Raman signal from the effect of the silicon substrate.

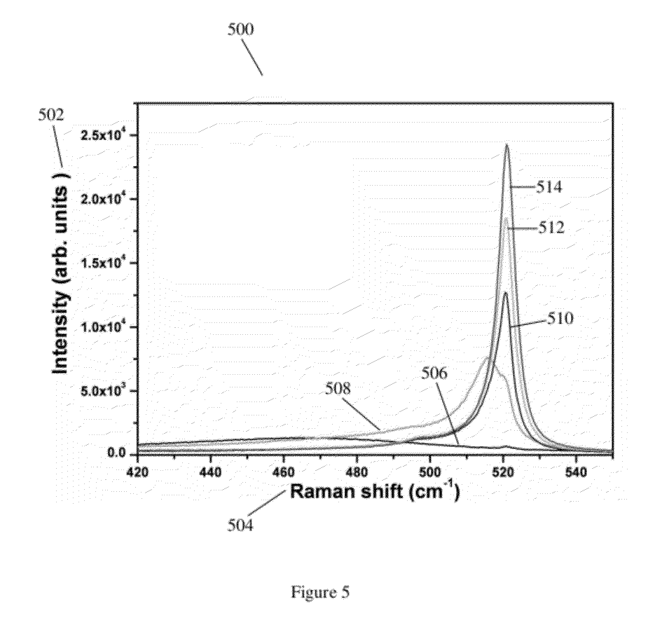

FIG. 5 shows a plot 500 of Raman data for a number of nanocrystalline Si/SiO₂ multilayer samples according to various embodiments. The plot 500 is shown in terms of the intensity 502 against the Raman shift 504. The Raman data was obtained using a custom-built in-house apparatus.

FIG. 5 shows the evolution of the Raman spectra for the as-deposited sample 506 without annealing and the samples annealed at 700° C. 508, 900° C. 510, 1000° C. 512 and 1100° C. 514. Measurements of samples annealed at other temperatures were not shown in FIG. 5 in order to demonstrate clearly the evolution of the Raman spectra.

FIG. 5 shows that the Raman peak at around 520 cm⁻¹, which is generally ascribed to crystalline silicon, increased with an increase in the annealing temperature. Accordingly, the results show that the crystalline content of silicon increases with an increase in the annealing temperature when the temperature is higher than about 700° C. The results conform to studies on nanocrystallization of a-Si/SiO₂ superlattices by high temperature thermal annealing, as known in the art.

After the deposition and annealing of the nc-Si/SiO₂ multilayer structure, a layer of SiO₂ with a thickness of about 100 nm was deposited on top of the multilayer structure to passivate the multilayer structure.

### Device Design and Fabrication

The active region of the light emitting device of various embodiments was defined by deep ultra-violet (UV) lithography and etched via a reactive ion etching process through the nc-Si/SiO₂ multilayer structure to the thermal SiO₂ layer to expose the thermal SiO₂ on the silicon wafer. The active region was patterned into an interdigitated structure, with a top view as shown in the embodiment of FIG. 2C. The interdigitated structure includes fingers of the doped regions with the intrinsic regions disposed in between the doped regions. The interdigitated structure includes ten periods of instrinsic regions and doped regions. The intrinsic regions include the nc-Si/SiO₂ multilayer or multiple quantum well structures while the doped regions may be p⁺-polycrystalline silicon (p⁺-poly-Si) or n⁺-polycrystalline silicon (n⁺-poly-Si).

A layer of polycrystalline silicon (poly-Si) with a thickness of about 160 nm poly-Si was then deposited by low pressure chemical vapor deposition (LPCVD) at about 540° C., followed by an annealing process at about 575° C. for about 15 hours. During the deposition and annealing of the polycrystalline silicon layer, the temperature was consistently maintained below about 600° C. so as to minimise any effects on the optical and electrical properties of the nc-Si/SiO₂ multiple quantum well structures.

Subsequently, relatively high-dose implantations of boron and phosphorous were carried out to form the p⁺-doped polycrystalline silicon (poly-Si) contact and the n⁺-doped polycrystalline silicon (poly-Si) contact, respectively. A rapid thermal annealing process at about 1000° C. was then carried out to activate the dopant. The annealing duration was minimal, at about 1 second, in order to minimize its effect on the crystalline structures of the nc-Si/SiO₂ multiple quantum well structures.

The dopant concentrations for both the p⁺-poly-Si contact and the n⁺-poly-Si contact were approximately 5×10¹⁹ cm⁻³.

A light emission window was then pattered and formed by etching through the poly-Si layer to expose the SiO₂passivation layer on top of the active region.

A layer of aluminium of a thickness of about 7500 Å was then deposited. Selective patterning and etching were subsequently performed to define the electrodes.

The final device fabricated may be represented by the embodiments shown in FIGS. 2A to 2F. As shown by the cross-sectional transmission electron microscope (TEM) image in FIG. 2E, the interdigitated fingers of the interdigitated structure may consist of nc-Si/SiO₂ multiple quantum well in the middle and doped poly-Si regions on either side of the multiple quantum well. FIGS. 2E and 2F further show that the ultra-thin a-Si layers as deposited had been converted to nc-Si layers after a high temperature annealing process, in line with the micro-Raman spectroscopy measurement as shown in FIG. 5.

In various embodiments, the active region had the dimensions with length L₂ and width W₂ such that the light emission window size or area is L₂×W₂. The length L₂ was about 1 mm while the width W₂ was about 1 mm. Accordingly, the light emission window size is about 1 mm². The finger width, a, was about 10 μm, while the finger spacing, w, representing the multiple quantum well width varied from about 0.5 μm to about 2 μm for different samples fabricated.

Additionally, a light emitting device according to the embodiment of FIG. 1A was fabricated using a similar fabrication process as that for the light emitting device according to the embodiment of FIG. 2A. For the embodiment of FIG. 1A, the active region included similar nc-Si/SiO₂ multilayer multiple quantum well structures.

In various embodiments, the active region had the dimensions with length L₁ and width W₁ such that the light emission window size or area is L₁×W₁. The length L₁ may be about 1 mm and the width W₁ may be about 1 μm.

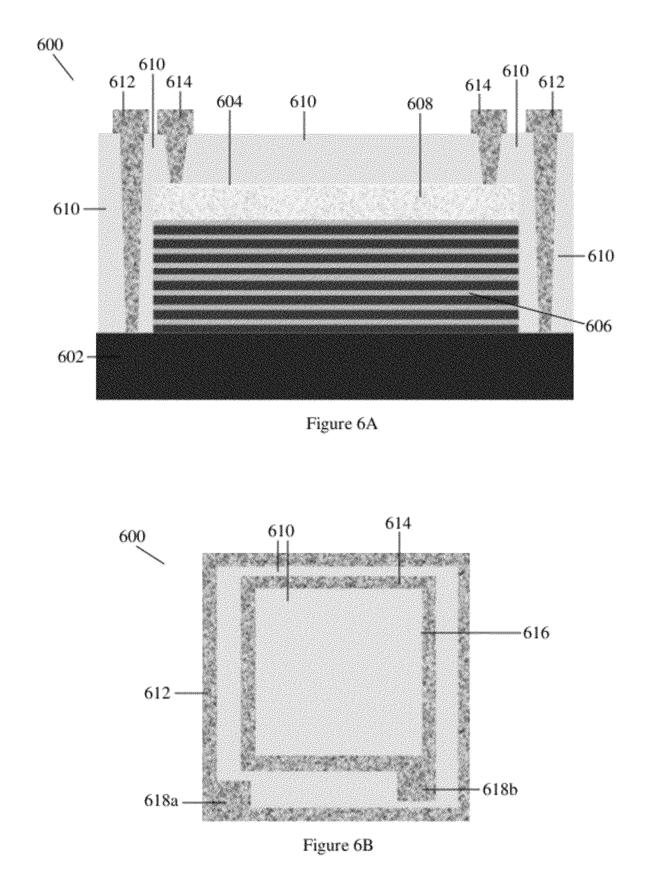

For the purposes of comparison, a conventional vertical-current-injection light emitting device was fabricated using similar nc-Si/SiO₂ multiple quantum well structures. FIG. 6A shows a side view of the vertical-current-injection light emitting device 600 on a p-doped silicon substrate 602, that was fabricated.

The light emitting device 600 includes an active region 604. The active region 604 includes the multiple quantum well (MQW) structure 606 and a layer of n⁺-doped polycrystalline silicon 608 on top of the multiple quantum well (MQW) structure 606. The MQW structure 606 includes alternating layers of nc-Si and SiO₂. The deposition and fabrication process of the nc-Si/SiO₂ MQW 606 was similar to that for the lateral-current-injection light emission device fabricated according to various embodiments. The layer of n⁺-doped polycrystalline silicon 608 acted as a semi-transparent electrode and had a thickness of about 100 nm.

The light emitting device 600 further includes a silicon dioxide region 610 surrounding the active region 604. Openings were created in the silicon dioxide region 610 to allow the formation of aluminium electrodes 612 and 614. The electrodes 612 were provided to contact the p-doped silicon substrate 602 while the electrodes 614 were provided to contact the layer of n⁺-doped polycrystalline silicon 608.

As shown in FIG. 6B as a top view of the light emitting device 600, the electrode 612 was formed to surround the perimeter of the light emitting device 600 while the electrode 614 was formed to surround the perimeter of the light emission window 616. The area of the light emission window 616 for the light emitting device 600 was approximately 1.2 mm×1.2 mm, substantially consistent with the area of the light emission window of the lateral-current-injection light emission device fabricated according to various embodiments.

The light emitting device 600 further included pads 618a and 618b for the purpose of electrical probing of the light emitting device 600 and for obtaining measurement results. The pads 618a and 618b had a size of approximately 0.4 mm×0.4 mm.

### Experimental Data

The measurement data for the light emitting device of the embodiment of FIG. 2A are generally provided for a device having the parameters of about 10 nm for the thickness of the nc-Si layers, a thermal annealing process at a temperature of about 1000° C. and a duration of about 1 hour for the annealing of the nc-Si/SiO2 multiple quantum well structure and about 0.5 μm for the finger spacing, w, unless otherwise stated.

Electroluminescence (EL) spectra were taken at room temperature using a PDS-1 photomultiplier tube (PMT) detector together with a monochromator.

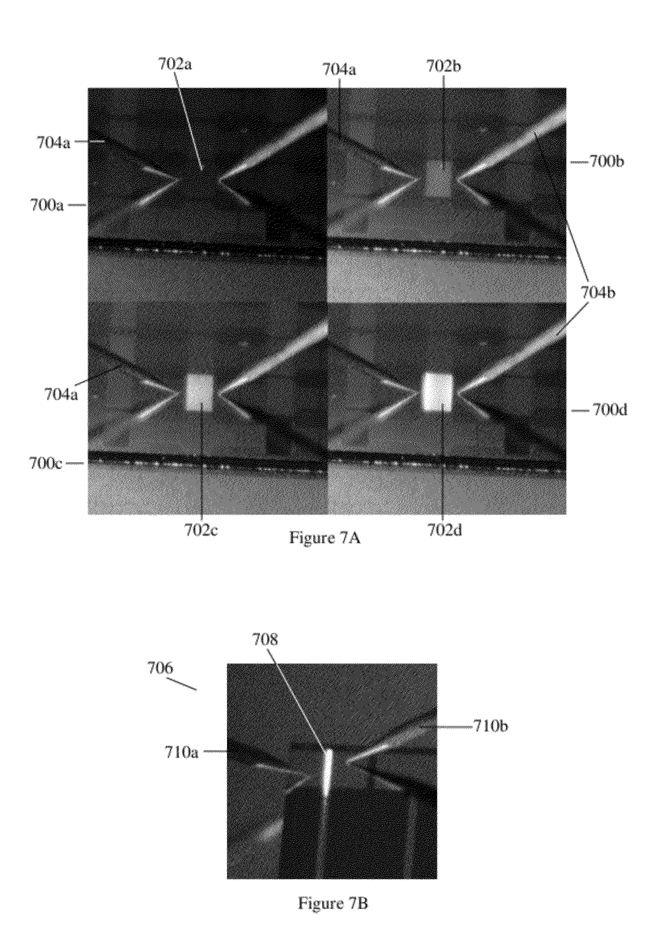

FIG. 7A shows photographs 700a, 700b, 700c and 700d of electroluminescence (EL) patterns under reverse biasing voltages of about 0 V, 6 V, 10 V and 18 V, respectively, for the light emitting device fabricated according to the embodiment of FIG. 2A.

FIG. 7A shows that relatively strong electroluminescence emission may be observed in normal daylight from the light emission windows 702b, 702c and 702d of photographs 700b, 700c and 700c, respectively, when a reverse bias voltage larger than 6 V was applied via probes 704a and 704b to the light emitting device fabricated according to the embodiment of FIG. 2A. At a voltage of 0 V, no electroluminescence emission is observable from the light emission window 702a of photograph 700a. Accordingly, various embodiments provide a light emitting device with a relatively low turn-on voltage of about 6 V.

In contrast, a forward bias voltage of about 40 V or more may be necessary to induce observable electroluminescence emission in a similar wavelength region (data not shown).

FIG. 7B shows a photograph 706 of electroluminescence pattern under reverse bias for the light emitting device fabricated according to the embodiment of FIG. 1A, illustrating relatively strong electroluminescence emission that may be observed in normal daylight from the light emission window 708 when a reverse bias voltage of about 10 V was applied via probes 710a and 710b.

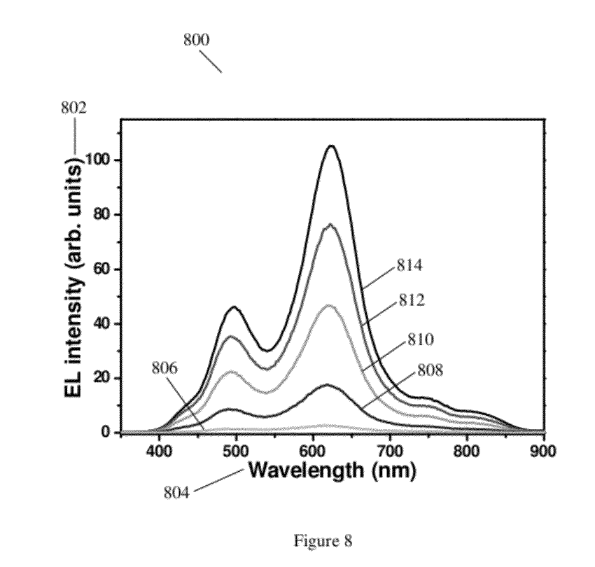

FIG. 8 shows a plot 800 of electroluminescence (EL) spectra under different reverse bias voltages for the light emitting device fabricated according to the embodiment of FIG. 2A. The plot 800 is shown in terms of the EL intensity 802 against wavelength 804.

FIG. 8 shows the EL spectra obtained when the light emitting device was reverse biased at voltages of 6 V 806, 9 V 808, 12 V 810, 15 V 812 and 18 V 814. The device used to obtain the photographs of FIG. 7A and the EL spectra of FIG. 8 is the same light emitting device. The results of FIG. 8 illustrate that the EL intensity 802 at the wavelength 804 range of about 400 nm to about 900 nm increased approximately linearly as the magnitude of the reverse bias voltage was increased.

An EL spectra measurement was also performed when the light emitting device was forward biased at an applied voltage of about 50 V (data not shown). The results indicated that the spectral shape was similar to that of the reverse biased induced EL spectra. However, the intensity of the EL spectra under forward biasing at the voltage of 50 V is approximately 10 times weaker than that of the intensity of the EL spectra under reverse biasing at the voltage of 10 V. This indicates that the EL emission may not be ascribed to the direct recombination of electrons and holes due to the quantum confinement effect in the nc-Si layers.

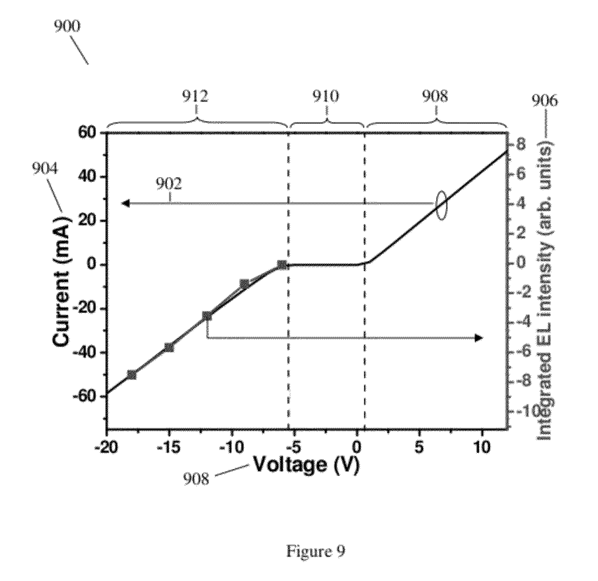

FIG. 9 shows a plot 900 of the current-voltage (I-V) characteristics 902 and the integrated EL intensity for the light emitting device fabricated according to the embodiment of FIG. 2A. The plot 900 is shown in terms of the current 904 and the integrated EL intensity 906 as a function of the applied voltage 908. The current-voltage (I-V) characteristics 902 were measured using a Keithley 4200 semiconductor characterization system.

FIG. 9 shows that the I-V characteristics 902 may be approximated by three regions in the voltage range from about −20 V to about 12 V. Region 1 908 represents a linear region when the light emitting device was under forward biasing at a voltage larger than about 0.5 V. Region 2 910 represents a region of biasing voltage from about −6 V to about 0.5 V when the light emitting device was under relatively low current injection where no EL emission may be measured. Region 3 912 represents a second linear region when the light emitting device was under a relatively strong reverse biasing voltage larger than about 6 V.

Region 3 912 shows that relatively strong EL emission may be detected from the reverse-biased light emitting device when the reverse voltage was larger than about 6 V. A linear relationship may also be observed between the reverse current 904 and the integrated EL intensity 906. Further measurements (data not shown) showed that the linear relationship between the reverse current 904 and the integrated EL intensity 906 was valid over the entire detected EL spectrum.

The fabricated light emitting device includes an interdigitated structure which may be considered as p-i-n structures in a parallel connection, in which the intrinsic regions include the nc-Si/SiO₂ multiple quantum well structures. As generally known in the art, the electric field in the intrinsic region of a reversed biased p-i-n junction is relatively higher than that of a forward biased p-i-n junction. When the junction field is sufficiently large, hot carriers may be generated in the intrinsic region. Accordingly, the inventors believe that the visible EL emission originated from the impact ionization of hot carriers under a relatively high electric field when the device was reverse biased. Further, the linear characteristic between the reverse current 904 and the integrated EL intensity 906, as illustrated in FIG. 9, provides support that electron-hole recombinations may not contribute to the EL emission.

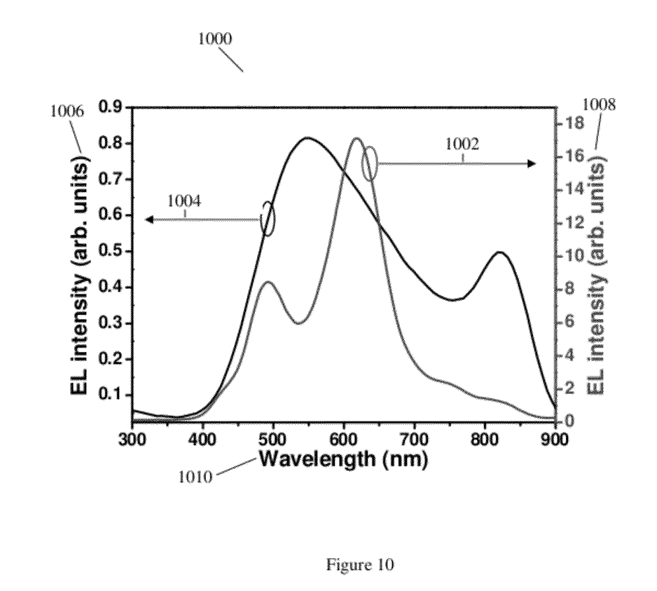

FIG. 10 shows a plot 1000 comparing the electroluminescence (EL) spectrum 1002 of the lateral-current-injection light emitting device fabricated according to the embodiment of FIG. 2A and the electroluminescence spectrum 1004 of the vertical-current-injection light emitting device fabricated according to the embodiment of FIG. 6A. The plot 1000 is shown in terms of the EL intensity 1006, 1008 against wavelength 1010.

The lateral-current-injection light emitting device and the vertical-current-injection light emitting device have approximately similar light emission window area and the same material system.

EL spectrum was measured under forward biasing of the vertical-current-injection light emitting device as no EL emission was detected under reverse biasing. Accordingly, the EL spectra were measured at a reverse bias voltage of about 9 V and a forward bias voltage of about 9 V, respectively for the lateral-current-injection light emitting device and the vertical-current-injection light emitting device.

FIG. 10 shows that under the same applied voltage magnitude, the EL spectrum 1002 of the lateral-current-injection light emitting device shows approximately 20 times stronger EL intensity 1006, 1008 than the EL spectrum 1004 of the vertical-current-injection light emitting device, while both devices have a current injection of approximately 10 mA. This illustrates an enhancement in the light emission efficiency of the lateral-current-injection light emitting device compared to the the vertical-current-injection light emitting device.

FIG. 10 further shows that the EL spectra 1002, 1004 are different, indicating that the EL emission of the lateral-current-injection light emitting device are based on different mechanisms compared to that of the vertical-current-injection light emitting device. The peaks for the EL spectrum 1002 and the EL spectrum 1004 are observed at different wavelengths.

As generally known, the EL spectrum induced in a vertical-current-injection light emitting device are based on two mechanisms consisting of quantum confinement effect of the nc-Si layers and defect-related recombination centers. Based on the EL spectrum 1004, the peak at approximately 820 nm may be ascribed to the quantum confinement effect while the peak at approximately 550 nm may be ascribed to the defect-related luminescence recombination centers.

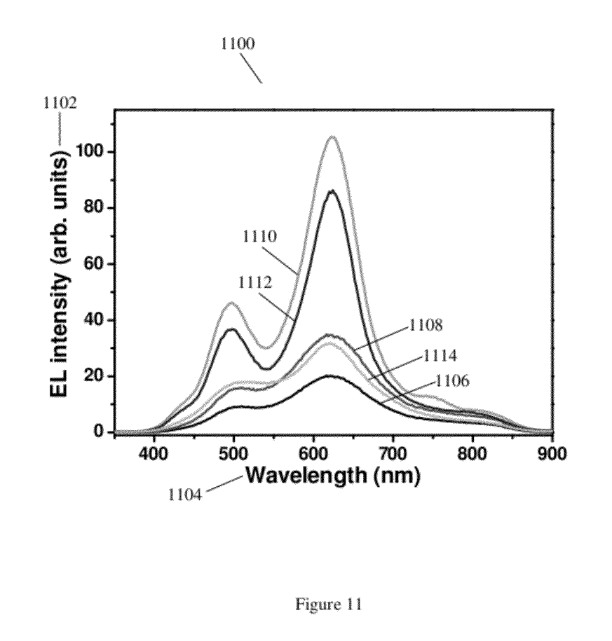

FIG. 11 shows a plot 1100 of electroluminescence (EL) spectra obtained under a reverse bias voltage of about 18 V for a number of samples of the light emitting device fabricated in accordance with the embodiment of FIG. 2A. The plot 1100 is shown in terms of the EL intensity 1102 against wavelength 1104.

FIG. 11 shows the EL spectra obtained for samples with the nc-Si/Si multiple quantum well structures annealed at temperatures of 700° C. 1106, 900° C. 1108, 1000° C. 1110, 1100° C. 1112 and 1150° C. 1114 in order to illustrate the effect of thermal annealing on the EL spectra. The inventors noted that the material system used in various embodiments should be annealed at a temperature higher than 700° C. in order to induce relatively strong visible EL.

FIG. 11 shows that the EL intensity 1102 increases with an increase in the annealing temperature up to about 1000° C. The EL intensity 1102 then decreases for annealing temperatures higher than 1000° C. This may be because a temperature of approximately 1000° C. may activate the luminescence states related to the hot carriers relatively more effectively. I-V measurements (data not shown) obtained were consistent with the results of FIG. 11 in that the current injection has a similar trend with the annealing temperature as that for the EL intensity 1102. This may also explain the thermal annealing effect on the EL intensity 1102.

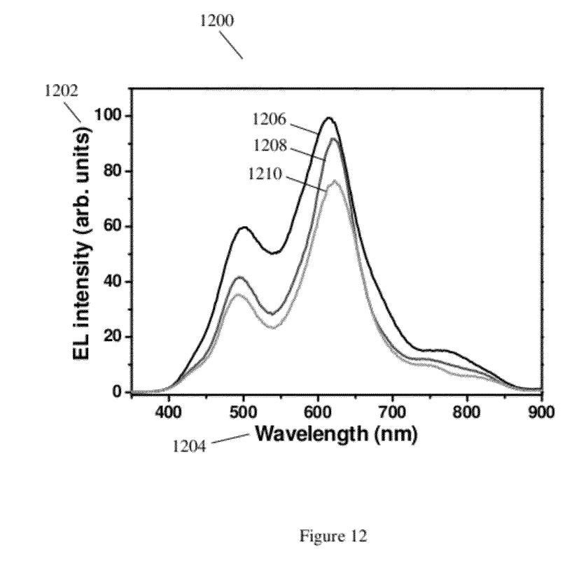

FIG. 12 shows a plot 1200 of electroluminescence (EL) spectra obtained under a reverse bias voltage of about 18 V for a number of samples of the light emitting device fabricated with different interdigitated finger spacings, in accordance with the embodiment of FIG. 2A. The plot 1200 is shown in terms of the EL intensity 1202 against wavelength 1204.

FIG. 12 shows the EL spectra obtained for samples having an interdigitated finger spacing, w, of about 0.5 μm 1206, 2 μm 1208 and 3 μm 1210 in order to illustrate the effect of the dimensions of the interdigitated finger structure on the EL spectra.

FIG. 12 shows that the EL intensity 1202 increases with a decrease in the finger spacing, w. This may be because a relatively higher current injection occurs in a device with a smaller finger spacing with a relatively lower resistance due to the shorter conduction length.

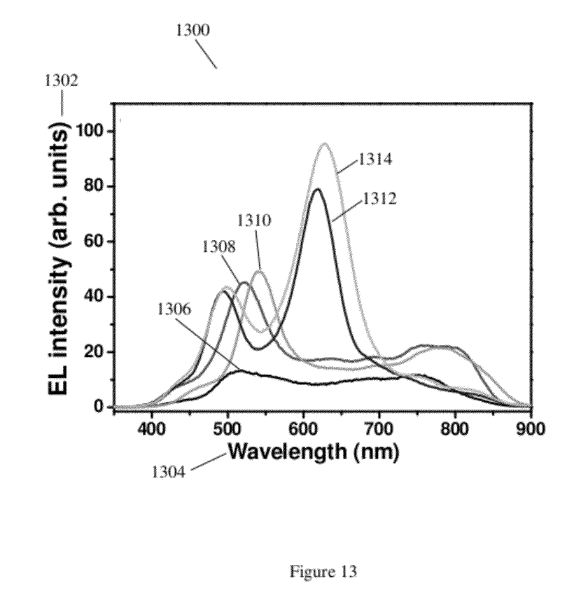

FIG. 13 shows a plot 1300 of electroluminescence (EL) spectra obtained under a reverse bias voltage of about 18 V for a number of samples of the light emitting device fabricated with different nanocrystalline silicon (nc-Si) layer thicknesses, in accordance with the embodiment of FIG. 2A. The plot 1300 is shown in terms of the EL intensity 1302 against wavelength 1304.

FIG. 13 shows the EL spectra obtained for samples having nanocrystalline silicon layers with a thickness of about 2 nm 1306, 3 nm 1308, 5 nm 1310, 7 nm 1312 and 10 nm 1314 in order to illustrate the effect of the dimensions of the multiple quantum well on the EL spectra and the device performance.

FIG. 13 shows that the thickness of the nc-Si layers affects the EL intensity 1302 and the spectral shape of the EL spectra. Accordingly, the EL spectrum of a light emitting device of various embodiments may be varied by changing the thickness of the nc-Si layers.

The EL intensity 1302 decreases with a decrease in the thickness of the nc-Si layers. This may be because lateral-current-injection becomes more challenging in thinner nc-Si layers. Therefore, at the same biasing voltage, which in this case is −18 V, the EL intensity 1302 is relatively higher for devices with thicker nc-Si layers.

As noted above, the reverse biased induced EL may not be caused by electron-hole recombinations due to the quantum confinement effect of the nc-Si layers. The inventors believe that the induced EL may be due to the impact ionization of hot carriers under a relatively high electric field when the device was reverse biased. Based on the observation of the effect of the thickness of the nc-Si layers on the EL spectral shape, the inventors believe that the thickness of the nc-Si layers may affect the generation of the hot carriers under reverse bias and the luminescent states due to the generation of hot carriers.

Various embodiments may provide a versatile technology platform, with flexibility in the design and integration of the light emitting device with, for example light extraction techniques and waveguides.

Light extraction techniques such as Fabry-Perot (F-P) cavity, photonic crystal structures and surface plasmons, may be applied to the bottom and top of the active region as there is no electrode on the bottom and top of the active region of the light emitting device of various embodiments.

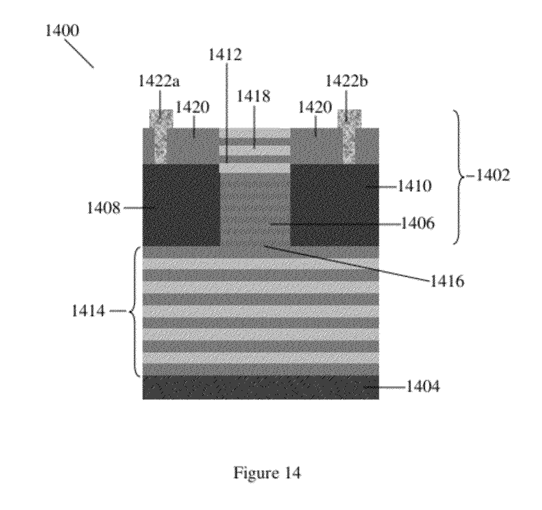

FIG. 14 shows a schematic side view of a structure 1400 including a light emitting device 1402 with Fabry-Perot (F-P) cavity, according to one embodiment. The structure 1400 may be provided on a substrate 1404. The substrate 1404 may be silicon. The light emitting device 1402 may be of the embodiments as shown in FIG. 1A or FIG. 2A.

In various embodiments, the structure 1400 may include an active region 1406 disposed between or sandwiched by a p-doped contact 1408 and an n-doped contact 1410. The active region 1406 includes a light emission window 1412, where light generated in the active region 1406 may be emitted.

The active region 1406 may include multiple quantum well (MQW) structures. The multiple quantum well may include alternating layers of conducting layers and non-conducting layers. In various embodiments, the conducting layers may be nanocrystalline silicon (nc-Si) layers while the non-conducting layers may be silicon dioxide (SiO₂) layers.

In various embodiments, each of the p-doped contact 1408 and the n-doped contact 1410 may include polycrystalline silicon (poly-Si). The p-doped contact 1408 may be implanted with the dopant boron (B) to form a p-type semiconductor. The n-doped contact 1410 may be implanted with the dopant phosphorus (P) to form an n-type semiconductor. In further embodiments, the p-doped contact 1408 may be doped with a relatively high amount of dopants to form a p⁺-type semiconductor. In further embodiments, the n-doped contact 1410 may be doped with a relatively high amount of dopants to form an n⁺-type semiconductor.

The structure 1400 may further include a bottom Bragg reflector 1414 in between the substrate 1404 and the bottom surface 1416 of the active region 1406. The Bragg reflector 1414 may be extended for disposal between the substrate 1404 and the p-doped contact 1408 and the n-doped contact region 1410, as shown in FIG. 14. The structure 1400 may further include a top Bragg reflector 1418 on the top surface, being the light emission window 1412, of the active region 1406. Each of the bottom Bragg reflector 1414 and the top Bragg reflector 1418 may include alternating layers of silicon nitride and silicon dioxide.

The structure 1400 may include a cladding oxide layer 1420. The cladding oxide layer 1420 may be silicon dioxide (SiO₂).

The structure 1400 may further include an electrode 1422a in contact with the p-doped contact 1408 and an electrode 1422b in contact with the n-doped contact 1410. Accordingly, the electrodes 1422a and 1422b are in electrical communication with the p-doped contact 1408 and the n-doped contact 1410, respectively. In various embodiments, the electrodes 1422a and 1422b may be metal electrodes. In a preferred embodiment, the electrodes 1422a and 1422b may be made of aluminium.

Based on the embodiment of FIG. 14, light generated in the active region 1406 may be reflected by the top Bragg reflector 1418 and the bottom Bragg reflector 1414. Accordingly, multiple reflections occur in the active region 1406, forming a Fabry-Perot (F-P) cavity to enhance light emission monochromaticity and intensity.

In contrast, the use of F-P cavity to enhance light emission monochromaticity and intensity remains a challenge for conventional vertical-current-injection light emitting device based on silicon/dielectric quantum well structures, due to the presence of electrodes over the active region.

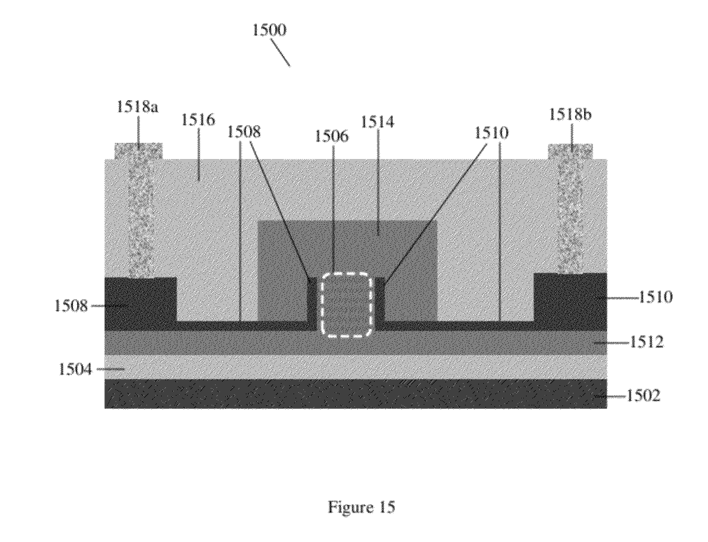

FIG. 15 shows a schematic side view of a waveguided light source 1500, according to one embodiment, provided on a substrate 1502 and a dielectric layer 1504. The substrate 1502 may be silicon. The dielectric layer 1504 may be a layer of silicon dioxide (SiO₂). The waveguided light source 1500 may include a lateral-current-injection structure of the embodiments of FIG. 1A or FIG. 2A.

In various embodiments, waveguided light source 1500 may include an active region 1506 disposed between or sandwiched by a p-doped contact 1508 and an n-doped contact 1510. The active region 1506 may include multiple quantum well (MQW) structures. The multiple quantum well may include alternating layers of conducting layers and non-conducting layers. In various embodiments, the conducting layers may be doped nanocrystalline silicon (nc-Si) layers while the non-conducting layers may be silicon nitride (SiN) layers. The nanocrystalline silicon (nc-Si) layers may be doped with erbium.

In various embodiments, each of the p-doped contact 1508 and the n-doped contact 1510 may include polycrystalline silicon (poly-Si). The p-doped contact 1508 may be implanted with the dopant boron (B) to form a p-type semiconductor. The n-doped contact 1510 may be implanted with the dopant phosphorus (P) to form an n-type semiconductor. In further embodiments, the p-doped contact 1508 may be doped with a relatively high amount of dopants to form a p⁺-type semiconductor. In further embodiments, the n-doped contact 1510 may be doped with a relatively high amount of dopants to form an n⁺-type semiconductor.

The waveguided light source 1500 may further include a layer of silicon nitride (SiN) 1512 in between the substrate 1502 and the active region 1506, the p-doped contact 1508 and the n-doped contact 1510.

The waveguided light source 1500 may further include a waveguide 1514 configured to substantially surround the active region 1506. The waveguide 1514 may be a rib waveguide. In various embodiments, the waveguide may be made of silicon nitride (SiN).

The waveguided light source 1500 may include a cladding oxide layer 1516. The cladding oxide layer 1516 may be silicon dioxide (SiO₂).

The waveguided light source 1500 may further include an electrode 1518a in contact with the p-doped contact 1508 and an electrode 1518b in contact with the n-doped contact 1510. Accordingly, the electrodes 1518a and 1518b are in electrical communication with the p-doped contact 1508 and the n-doped contact 1510, respectively. In various embodiments, the electrodes 1518a and 1518b may be metal electrodes. In a preferred embodiment, the electrodes 1518a and 1518b may be made of aluminium.

Based on the embodiment of FIG. 15, light generated in the active region 1506 and which is emitted, may be confined by the waveguide 1514. Light confined in the waveguide 1514 may then propagate within the waveguide 1514. In contrast, the use of a waveguide to confine the generated light remains a challenge for conventional vertical-current-injection light emitting device due to the presence of a top electrode and its associated high absorption of the generated light.

The embodiment of FIG. 15 may provide a waveguided light source at the optical communication wavelength of about 1500 nm. In alternate embodiments, the nanocrystalline layers of the MQW may be doped with other dopants, enabling the development of waveguided light sources for other wavelengths.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A light emitting device, comprising:
an active region comprising at least one p-i-n junction, the at least one p-i-n junction comprising a p-doped region, an intrinsic region and an n-doped region;
a first contact; and
a second contact, wherein the active region is disposed between the first contact and the second contact; and
wherein a voltage applied to the first contact and the second contact produces a current configured to flow between the first contact and the second contact in a direction substantially parallel to a surface of the intrinsic region of the active region configured to emit a light.

2. The light emitting device of claim 1, wherein the at least one p-i-n junction comprises a plurality of p-i-n junctions.

3. The light emitting device of claim 2, wherein adjacent p-i-n junctions of the plurality of p-i-n junctions are configured back-to-back to form a p-i-n-i-p structure or an n-i-p-i-n structure.

4. The light emitting device of claim 3, wherein each of the intrinsic regions of the plurality of p-i-n junctions comprises a multiple quantum well.

5. The light emitting device of claim 4, wherein the multiple quantum wells comprise alternating layers of a conducting layer and a non-conducting layer.

6. The light emitting device of claim 4, wherein the multiple quantum wells comprise alternating layers of nanocrystalline silicon and silicon dioxide.

7. The light emitting device of claim 5, wherein the conducting layers of the multiple quantum wells of the intrinsic regions of the plurality of p-i-n junctions are in electrical communication with each other.

8. The light emitting device of claim 7, wherein the intrinsic regions are arranged in an interdigitated structure.

9. The light emitting device of claim 8, wherein the first contact comprises a p-doped contact and the second contact comprises an n-doped contact.

10. The light emitting device of claim 9, further comprising a first electrode in electrical communication with the p-doped contact and a second electrode in electrical communication with the n-doped contact.

11. The light emitting device of claim 8, further comprising a first Bragg reflector disposed between a first surface of the active region and a substrate and a second Bragg reflector disposed on a second surface of the active region opposite the first surface.

12. The light emitting device of claim 11, wherein each of the first Bragg reflector or the second Bragg reflector comprises alternating layers of silicon nitride and silicon dioxide.

13. The light emitting device of claim 8, further comprising a waveguide configured to substantially surround the active region.

14. The light emitting device of claim 13, wherein the multiple quantum wells comprise alternating layers of erbium-doped nanocrystalline silicon and silicon nitride.

15. The light emitting device of claim 14, further comprising a layer of silicon nitride disposed between a surface of the active region and a substrate.

16. A method of forming a light emitting device, comprising:
providing an active region comprising at least one p-i-n junction, the at least one p-i-n junction comprising a p-doped region, an intrinsic region and an n-doped region;
providing a first contact; and
providing a second contact, wherein the active region is disposed between the first contact and the second contact; and
wherein a voltage applied to the first contact and the second contact produces a current configured to flow between the first contact and the second contact in a direction substantially parallel to a surface of the intrinsic region of the active region configured to emit a light.

17. A light emitting device, comprising:
an active region comprising an intrinsic region;
a first contact; and
a second contact, wherein the active region is disposed between the first contact and the second contact; and
wherein a voltage applied to the first contact and the second contact produces a current configured to flow between the first contact and the second contact in a direction substantially parallel to a surface of the intrinsic region of the active region configured to emit a light.

18. The light emitting device of claim 17, wherein the intrinsic region comprises a multiple quantum well.

19. The light emitting device of claim 18, further comprising a first Bragg reflector disposed between a first surface of the active region and a substrate and a second Bragg reflector disposed on a second surface of the active region opposite the first surface.

20. The light emitting device of claim 18, further comprising a waveguide configured to substantially surround the active region.
